(19) United States
(12) Patent Application Publication
(10) Pub. No.: US 2007/0026687 A1
(43) Pub. Date: Feb. 1, 2007

(54) Oxygen-rich gas supplying apparatus provided with a condensate removal unit

(75) Inventor: Tai Jin Kim, Seoul (KR)

Correspondence Address: BACON & THOMAS, PLLC, 625 SLATERS LANE, FOURTH FLOOR, ALEXANDRIA, VA, 22314, US

(73) Assignee: Biotel Co., Ltd., Hwaseong-gun, Gyewonggi-do (KR)

(21) Appl. No.: 10/552,890

(22) PCT Filed: Apr. 12, 2004
(86) PCT No.: PCT/KR04/00841

§ 371 Date: Oct. 11, 2005

(30) Foreign Application Priority Data
Apr. 11, 2003 (KR) 20-2003-0011188
Sep. 29, 2003 (KR) 20-2003-0030683

(51) Int. Cl. H01L 21/31

(52) U.S. Cl. 438/761

(57) ABSTRACT

An apparatus for supplying an oxygen-rich gas includes an oxygen-rich gas generating device for generating an oxygen-rich gas; and a condensate removal unit for removing condensates occurring in a transfer line from the oxygen-rich gas. The condensate removal unit has an inlet, an outlet and a drain port and the transfer line is connected to the inlet of the condensate removal unit. The drain port is closed by a solenoid valve which is selectively opened to discharge condensates collected in the condensate removal unit by an electric power applied thereto. A controller controls operations of the oxygen-rich gas generating device and the solenoid valve. The condensate removal unit contains a moisture filter for filtering off moisture in the oxygen-rich gas in a flowing path of the oxygen-rich gas. The moisture filter is formed with a multiplicity of pores by sintering polyethylene powder.

### FIELD of THE INVENTION

The present invention relates to an apparatus for supplying an oxygen-rich gas; and, more particularly, to an oxygen-rich gas supplying apparatus including a condensate removal unit capable of efficiently removing condensates and/or moisture from an oxygen-rich gas, thereby preventing the condensates and/or moisture from being supplied to a user together with the oxygen-rich gas to increase the user's pleasant feel.

### BACKGROUND OF THE INVENTION

A conventional oxygen-rich gas supplying apparatus includes an oxygen-rich gas generating device and a transfer line such as a pipe or tube for transferring an oxygen-rich gas from the oxygen-rich gas generating device to a desired place.

There have been provided various types of oxygen-rich gas generating devices, e.g., a pressure swing adsorption (PSA) type device and a membrane separation type device. The oxygen-rich gas generating device separates an ambient air introduced therein into an oxygen-rich gas and a nitrogen-rich gas. The oxygen-rich gas is supplied through the transfer line to the desired place to be inhaled by a user, whereas the nitrogen-rich gas is discharged to outside.

The oxygen-rich gas transfer line is at one end connected to an outlet port of the oxygen-rich gas generating device. In case the desire place is located far from the oxygen-rich gas producing apparatus, a pumping unit is used to apply a pressure to the oxygen-rich gas so that the latter is transferred to the desired place.

The oxygen-rich gas flowing in and along the oxygen-rich gas transfer line contains moisture which may be condensed due to differences in pressure and/or temperature between inside and outside of the line. The condensates occurring in the line may cause corrosion of the line and/or the pumping unit. Further, the moisture and/or condensates may be discharged together with the oxygen-rich gas to the use, thereby making the user unpleasant.

### SUMMARY OF THE INVENTION

It is, therefore, an object of the present invention to provide an oxygen-rich gas supplying apparatus including a condensates removal unit capable of efficiently removing condensates and/or moisture from an oxygen-rich gas transferred from an oxygen-rich gas generating device, thereby increasing pleasant feel of a user.

In accordance with an aspect of the present invention, there is provided an apparatus for supplying an oxygen-rich gas, including: an oxygen-rich gas generating device for generating an oxygen-rich gas; a transfer line for transferring the oxygen-rich gas discharged from the oxygen-rich gas generating device; a condensate removal unit for removing condensates occurring in the transfer line from the oxygen-rich gas, the condensate removal unit having an inlet, an outlet and a drain port, the transfer line being connected to the inlet of the condensate removal unit; a discharge line for discharging the oxygen-rich gas to a desired place, the discharging line being connected to the outlet of the condensate removal unit.

In accordance with another aspect of the present invention, there is provided an apparatus for supplying an oxygen-rich gas, including: an oxygen-rich gas generating device for generating an oxygen-rich gas; a transfer line for transferring the oxygen-rich gas from the oxygen-rich gas generating device; a first housing having a first inlet, a first outlet and a drain port, the transfer line being connected to the first inlet of the first housing; a second housing having a second inlet and a second outlet, the second housing communicating with the first housing through a connection line both ends of which are connected to the first outlet and the second inlet, respectively; a discharge line for discharging the oxygen-rich gas to a desired place, the discharging line being connected to the outlet of the second housing.

### BRIEF DESCRIPTION OF THE INVENTION

The above and other objects and features of the present invention will become apparent from the following description of preferred embodiments given in conjunction with the accompanying drawings, in which:

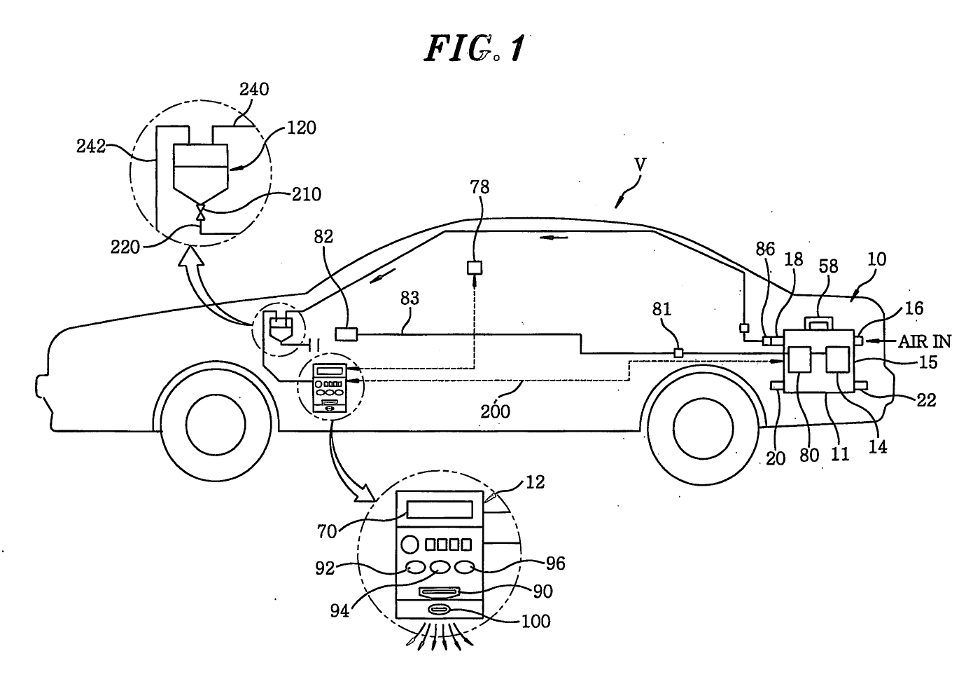

FIG. 1 offers a schematic view of an oxygen-rich gas supplying apparatus in accordance with a first preferred embodiment of the present invention;

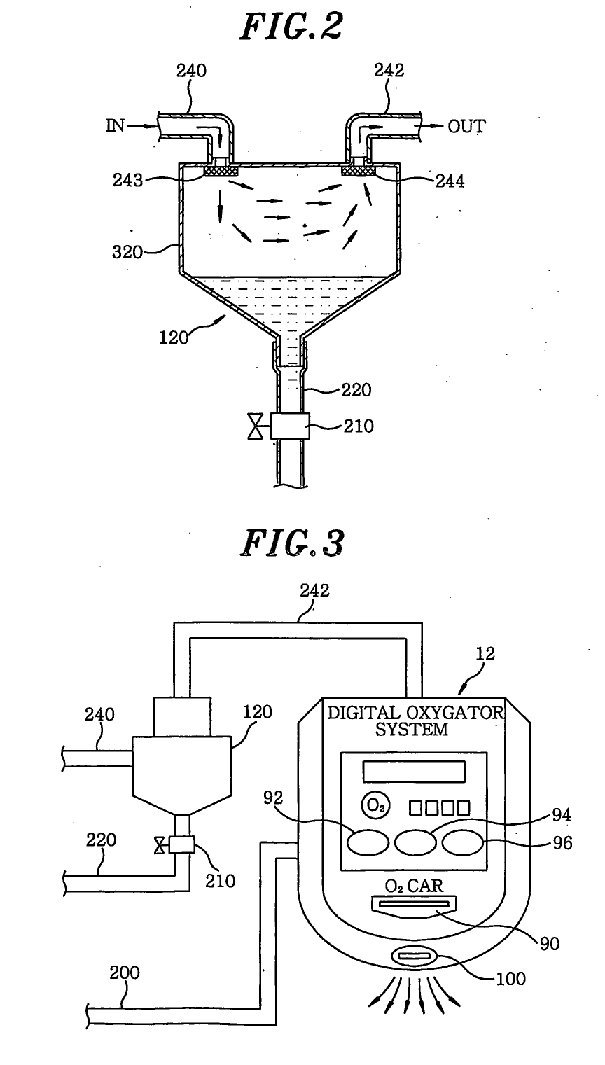

FIG. 2 provides an enlarged cross sectional view of a condensate removal unit of the oxygen-rich gas supplying apparatus in accordance with the first preferred embodiment of the present invention;

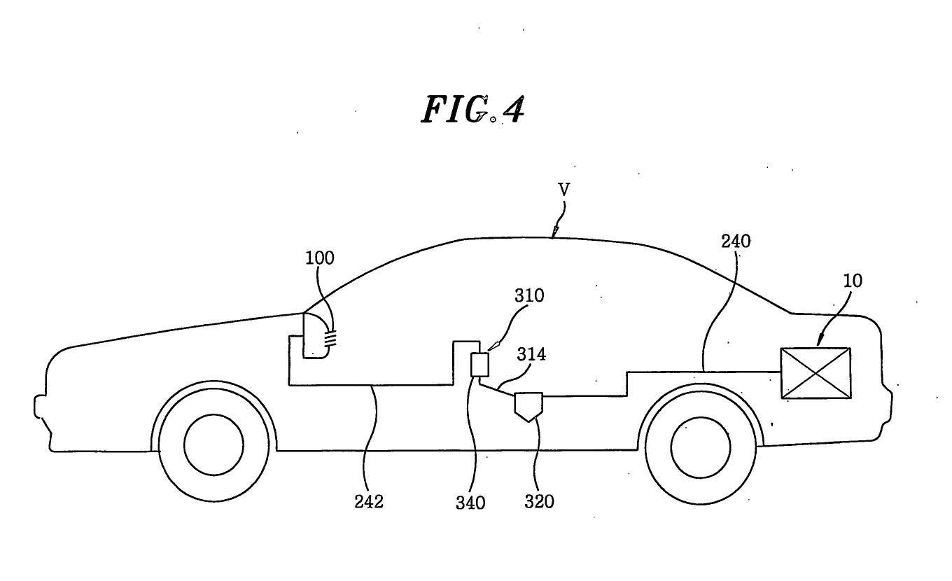

FIG. 3 presents a schematic view showing a control panel of the oxygen-rich gas supplying apparatus in accordance with the first preferred embodiment of the present invention;

FIG. 4 sets forth a schematic view of an oxygen-rich gas supplying apparatus in accordance with a second preferred embodiment of the present invention; and

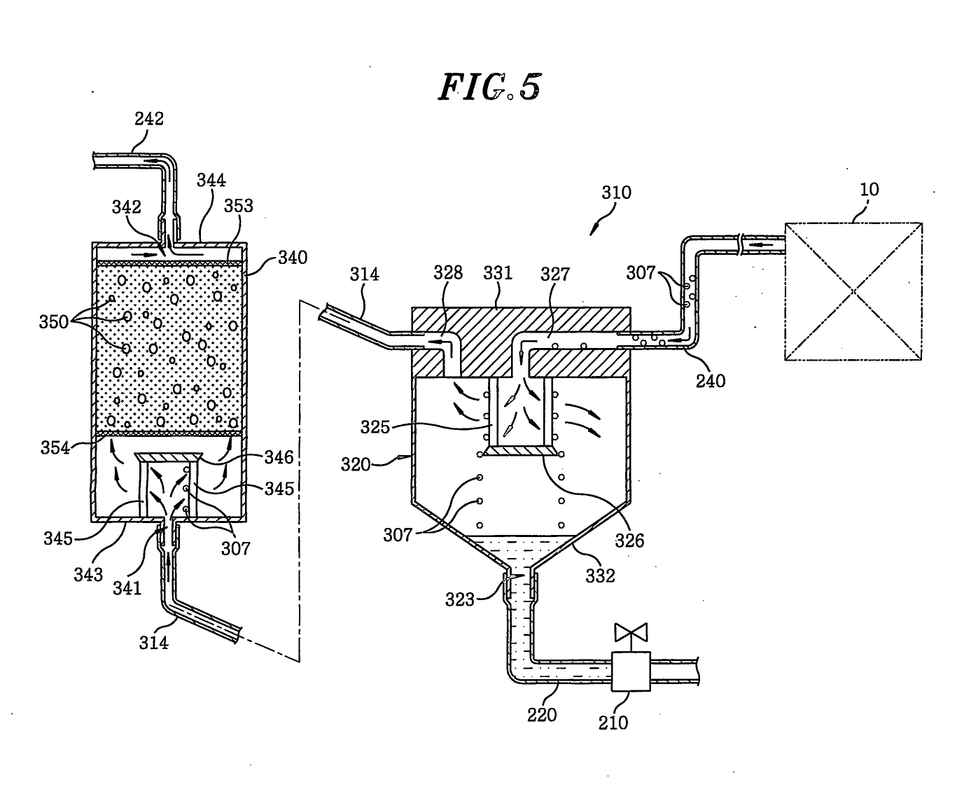

FIG. 5 depicts a cross sectional view of a condensate removal unit of the oxygen-rich gas supplying apparatus in accordance with the second preferred embodiment of the present invention.

### DESCRIPTION OF SPECIFIC EMBODIMENTS

Preferred embodiments of the present invention will now be described with reference to FIGS. 1 to 5. In the following description, like reference numerals in the drawings represents like parts.

Referring to FIG. 1, there is schematically shown an oxygen-rich gas supplying apparatus in accordance with a first preferred embodiment of the present invention. The oxygen-rich gas supplying apparatus includes an oxygen-rich gas generating device 10 for generating an oxygen-rich gas, the oxygen-rich gas generating device 10 being disposed in, e.g., a trunk of an automotive vehicle V, a transfer line 240 such as a pipe or tube for transferring the oxygen-rich gas from the oxygen-rich gas generating device 10, a condensate removal unit 120 for removing condensates occurring in the transfer line 240 from the oxygen-rich gas, and a discharge line 242 for discharging the oxygen-rich gas to a desired place.

The oxygen-rich gas generating device 10 has a main body 15 with an inlet port 16 and an outlet port 18. Ambient air is introduced through the inlet port 16 into the main body 15. The introduced air is separated into an oxygen-rich gas and a nitrogen-rich gas by an oxygen separator (not shown) disposed in the main body 15. The oxygen-rich gas is discharged through the outlet port 18 from the main body 15, while the nitrogen-rich gas is discharged through a nitrogen-rich gas outlet 20 to outside.

The oxygen-rich gas generating device 10 also has a controller 14 which is electrically connected via an inverter 80 to a power source, e.g., a cigarette port 82 within the vehicle. In this embodiment, the inverter 80 is connected to the cigarette port 82 by using a cable 83 and a connector 81, and functions to convert DC power to AC power.

The transfer line 240 is at one end thereof connected to the outlet port 18 of the main body 15 of the oxygen-rich gas generating device 10. The transfer line 240 extends through a roof portion, a bottom portion or a side portion of the vehicle to a front side of the vehicle. Preferably, the transfer line 240 has a length of 1 m or greater in order to have most of moisture contained in the oxygen-rich gas flowing in the transfer line 240 condensed due to, e.g., a difference in temperature between inside and outside of the transfer line 240.

Referring to FIG. 3, there is shown in detail a control panel 12 for manipulating the oxygen-rich gas supplying apparatus. The control panel 12 is disposed near a driver seat inside the vehicle. The control panel 12 has a display window 70, several mode buttons 92, 94, 96, a power button 90 and an oxygen-rich gas discharge nozzle 100. The display window 70 displays an oxygen concentration detected by an oxygen sensor 78 installed in the vehicle V and/or an operating mode set by pushing each mode button, e.g., a low, a middle or a high oxygen concentration mode. The control panel 12 is electrically connected through a cable 200 to the controller 14 which controls an amount of the oxygen-rich gas generated and a condensate discharge valve to be described later in response to a signal from the control panel. The control panel 12 may be wirelessly connected to the controller 14.

The condensate removal unit 120 is installed in the vicinity of the control panel 12. As shown in FIG. 2, the condensate removal unit 120 has an inlet, an outlet and a drain port. The transfer line 240 and the discharge line 242 are connected to the inlet and the outlet of the condensate removal unit 120, respectively, so that they communicate with each other through the condensate removal unit 120. The discharge line 242 is connected with the oxygen-rich gas discharge nozzle 100 provided in the control panel 12 and the oxygen-rich gas flowing in and along the discharge line 242 is therefore discharged from the nozzle 100. Preferably, the discharge line 242 is a flexible tube or a metallic tube which can be bent and maintain its bent configuration.

With such arrangements, even though moisture contained in the oxygen-rich gas flowing in the transfer line 240 is condensed due to differences in temperature and pressure between inside and outside of the line, the condensates are dropped and collected in the condensate removal unit 120. Accordingly, the oxygen-rich gas without condensates flows in and along the discharge line 242 to be discharged from the oxygen-rich gas discharge nozzle 100 to inside of the vehicle V.

Further, in order to filter off moisture in the oxygen-rich gas, it is preferable that a first and a second moisture filter 243, 244 are provided in a flowing path of the oxygen-rich gas, e.g., at the inlet and the outlet in the condensate removal unit 120. Preferably, the moisture filters 243, 244 are formed with a multiplicity of pores by sintering polyethylene powder. While the oxygen-rich gas containing moisture passes through the pores of the moisture filters 243, 244, the moisture is condensed due to the increased pressure. Preferably, the pores of the first moisture filter 243 have a sufficient large size to allow the condensates to pass therethrough into the condensate removal unit 120, and those of the second moisture filter 244 have a sufficient small size to prevent the condensates generated thereby from entering the discharge line 242.

Preferably, each of the first and the second moisture filter 243, 244 is a hollow fiber membrane filter or a flat sheet membrane filter which pressurizes the moisture contained in the oxygen-rich gas passing therethrough to be condensed.

The condensate removal unit 120 has a funnel-shaped lower portion and the drain port is provided at, e.g., a lowermost thereof. The drain port is closed by a valve 210. Preferably, the valve 210 is a solenoid valve which is normally closed. The solenoid valve 210 is opened to discharge the condensates collected in the condensate removal unit by an electric power applied thereto. The controller 14 controls the solenoid valve 210 as well as the oxygen-rich gas generating device 10.

For example, the solenoid valve 210 is controlled to be opened for about 10-20 seconds by the controller 14 in case the oxygen-rich gas generating device 10 is operated for about 10 minutes. Alternatively, a condensate removal button (not shown) may be provided on the control panel 12 so that the solenoid valve 210 is actuated to open the condensate removal unit 120 by pushing the condensate removal button.

When the valve 210 is opened, the condensates collected in the condensate removal unit 120 are discharged through a drain pipe 220 to outside. The drain pipe 220 may be merged with a condensed water drain pipe 22 provided in the oxygen-rich gas generating device 10.

In this embodiment, although the oxygen-rich gas discharge nozzle 100 is provided to the control panel 12, it may be provided at any suitable place.

Further, a pumping unit (not shown) such as a blower is provided to urge the oxygen-rich gas to flow through the lines 240, 242 into the inside of the vehicle V.

Hereinafter, an oxygen-rich gas supplying apparatus including a condensate removal unit 310 in accordance with a second preferred embodiment of the present invention will be described in detail with reference to FIGS. 4 and 5.

The second embodiment is similar to the first embodiment except for the condensate removal unit 310.

The condensate removal unit 310 includes a first housing 320 containing a first moisture filter 325, and a second housing 340 containing a second moisture filter 345 and an adsorbent 350.

The first housing 320 has an upper thicker portion 331 with an inlet channel 327 and an outlet channel 328, and a funnel-shaped lower portion 332 with a drain port 323. The transfer line 240, one end of which is connected to the outlet port 18 of the main body 15 of the oxygen-rich gas generating device 10 (FIG. 1), is connected to the inlet channel 327 of the first housing 320. The first moisture filter 325 having a cylindrical shape is installed to surround a distal end of the inlet channel 327 such that an oxygen-rich gas introduced in the inlet channel 327 flows through the first moisture filter 325. A lower opened end of the first moisture filter 325 is clogged with a first cap 326. The first moisture filter 325 is formed by sintering polyethylene powder. Specifically, the first moisture filter 325 is formed by pressurizing the polyethylene powder in a cylindrical shape and heating the cylindrically shaped polyethylene powder to a temperature near the melting point thereof such that the powder particles are adhered to each other to keep the cylindrical shape. The first moisture filter 325 has a multiplicity of fine pores defined by the adjacent particles of the sintered powder. While the oxygen-rich gas containing moisture passes through the first moisture filter 325, pressure of the gas is increased, thereby resulting in condensation of the moisture in the gas. In this embodiment, although the first moisture filter 325 is formed by sintering the polyethylene powder, the present invention is not limited thereto. For example, a porous material such as a nonwoven fabric may be used to form the first moisture filter 325. Preferably, the first moisture filter 325 is a hollow fiber membrane filter or a flat sheet membrane filter which pressurizes the moisture contained in the oxygen-rich gas passing therethrough to be condensed.

The second housing 340 is of a cylindrical configuration and has an inlet 341 and an outlet 342 provided in a lower and an upper wall 343, 344, respectively.

The second moisture filter 345 having a cylindrical shape is installed to surround the inlet 341 such that an oxygen-rich gas introduced through the inlet 341 into the second housing 340 flows through the second moisture filter 345. An upper opened end of the second moisture filter 345 is clogged with a second cap 346. Similarly to the first moisture filter 325, the second moisture filter 345 is formed by sintering polyethylene powder. Preferably, the second moisture filter 345 is formed of the polyethylene powder with a smaller particle size than in the first moisture filter 325 so that the second moisture filter 345 has smaller pores than those of the first moisture filter 325. As is in case of the first moisture filter 325, while the oxygen-rich gas containing moisture passes through the second moisture filter 345, the moisture in the gas is condensed due to an increased gas pressure. Alternatively, the second moisture filter 345 may be formed of a porous material such as a nonwoven fabric. Preferably, the second moisture filter 345 is a hollow fiber membrane filter or a flat sheet membrane filter which pressurizes the moisture contained in the oxygen-rich gas passing therethrough to be condensed.

Further, the adsorbent 350 comprised of alumina particles is provided above the second moisture filter 345 in the second housing 340 and is held in place by a pair of support, e.g., an upper and a lower wire mesh 353, 354. Each of the upper and the lower wire mesh 353, 354 has a multiplicity of openings whose size is less than that of the alumina particles, thereby preventing the alumina particles from escaping therefrom. Alternatively, the adsorbent 350 may be comprised of silica gel.

The outlet channel 328 of the first housing 320 communicates with the inlet 341 of the second housing 340 through a connection line 314 such as a pipe or tube. For the purpose of convenient illustration, although there is shown in FIG. 5 that the inlet 341 of the second housing 340 is located at a lower level than the outer end of the outlet channel 328, the inlet 341 is actually located at a higher level than the outer end of the outlet channel 328 so that condensates generated in the second moisture filter 345 flows through the connection line 314 to the first housing 320 and is collected therein (see FIG. 4).

The outlet 342 of the second housing 340 communicates with the oxygen-rich discharge nozzle 100 (FIGS. 1 and 3) through the discharge line 242.

In this embodiment, each of the first housing 320 and the second housing 340 may be constructed with two or more separable parts in order to make maintenance of the condensate removal unit 310 convenient. In addition, the adsorbent 350 and the upper and the lower wire mesh 353, 354 may be provided as a module for easy replacement of the adsorbent 350 which has lost its moisture adsorbing capability.

Functions of the condensate removal unit 310 of the present invention will now be described.

When the oxygen-rich gas generating device 10 is operated, an oxygen-rich gas discharged from the device 10 flows through the transfer line 240 into the first housing 320 and then passes through the first moisture filter 325. At that time, some of moisture contained in the oxygen-rich gas is condensed while flowing along the transfer line 240 and through the first moisture filter 325 as described above. The pores of the first moisture filter 325 have a large size sufficient to transmit the condensates 307 therethrough so that the condensates 307 are dropped and collected in the lower portion of the first housing 320.

The oxygen-rich gas, which has passed the first moisture filter 325, flows through the outlet channel 328 and the connection line 314 into the second housing 340. Some of the remaining moisture in the oxygen-rich gas is condensed while passing through the second moisture filter 325. The second moisture filter 325 has small-sized pores sufficient to block the condensates 307. Therefore, the condensates 307 flow through the connection line 314 to the first housing 320 counter to the flow direction of the oxygen-rich gas and are collected therein.

Meanwhile, the oxygen-rich gas passing the second moisture filter 345 flows through the adsorbent 350, and the moisture in the oxygen-rich gas is adsorbed by the adsorbent 350. Then, the oxygen-rich gas with little or no moisture flows in and along the discharge line 242 to be discharged from the discharge nozzle 100 into inside of the vehicle V.

According to the present invention, moisture and condensates are prevented from being supplied to a user together with the oxygen-rich gas, thereby increasing the user's pleasant feel.

Further, in case the oxygen-rich gas discharge nozzle 100 is provided in the control panel 12 has, an operator can inhale the oxygen-rich gas while manipulating the control panel 12.

While the invention has been shown and described with respect to the preferred embodiments, it will be understood by those skilled in the art that various changes and modifications may be made without departing from the spirit and scope of the invention as defined in the following claims.

1. An apparatus for supplying an oxygen-rich gas, comprising:
an oxygen-rich gas generating device for generating an oxygen-rich gas;
a transfer line for transferring the oxygen-rich gas discharged from the oxygen-rich gas generating device;
a condensate removal unit for removing condensates occurring in the transfer line from the oxygen-rich gas, the condensate removal unit having an inlet, an outlet and a drain port, the transfer line being connected to the inlet of the condensate removal unit;
a discharge line for discharging the oxygen-rich gas to a desired place, the discharging line being connected to the outlet of the condensate removal unit.

2. The apparatus of claim 1, wherein the condensate removal unit has a funnel-shaped lower portion and the drain port is provided at the funnel-shaped lower portion.

3. The apparatus of claim 1, wherein the drain port is closed by a valve.

4. The apparatus of claim 3, wherein the valve is selectively opened to discharge condensates collected in the condensate removal unit by an electric power applied thereto.

5. The apparatus of claim 4, further comprising a controller for controlling operations of the oxygen-rich gas generating device and the valve.

6. The apparatus of claim 5, further comprising a control panel for manipulating the controller, the control panel having an oxygen-rich gas discharge nozzle communicating with the discharge line.

7. The apparatus of claim 6, wherein the condensate removal unit is disposed near the oxygen-rich gas discharge nozzle.

8. The apparatus of claim 1, wherein the condensate removal unit contains a first moisture filter having a multiplicity of pores for filtering off moisture in the oxygen-rich gas in a flowing path of the oxygen-rich gas.

9. The apparatus of claim 8, wherein the condensate removal unit further contains a second moisture filter having a multiplicity of pores for filtering off moisture in the oxygen-rich gas in a flowing path of the oxygen-rich gas, the first and the second moisture filter being located near the inlet and the outlet of the condensate removal unit, respectively.

10. The apparatus of claim 8, wherein the first and the second moisture filter are each formed by sintering polyethylene powder.

11. The apparatus of claim 9, wherein the pores of the first moisture filter have a sufficient size to allow condensates to pass therethrough into the condensate removal unit, and those of the second moisture filter have a sufficient size to prevent condensates from passing therethrough.

12. The apparatus of claim 11, wherein the adsorbent is comprised of alumina particles and is held in place by a pair of supports with openings whose size is less than that of the alumina particles.

13. The apparatus of claim 1, wherein the transfer line has a length of 1 m or greater.

14. An apparatus for supplying an oxygen-rich gas, comprising:
an oxygen-rich gas generating device for generating an oxygen-rich gas;
a transfer line for transferring the oxygen-rich gas from the oxygen-rich gas generating device;
a first housing having a first inlet, a first outlet and a drain port, the transfer line being connected to the first inlet of the first housing;
a second housing having a second inlet and a second outlet, the second housing communicating with the first housing through a connection line both ends of which are connected to the first outlet and the second inlet, respectively;
a discharge line for discharging the oxygen-rich gas to a desired place, the discharging line being connected to the outlet of the second housing.

15. The apparatus of claim 14, wherein the first housing contains a first moisture filter for filtering off moisture in the oxygen-rich gas in a flowing path of the oxygen-rich gas and/or the second housing contains a second moisture filter for filtering off moisture in the oxygen-rich gas in a flowing path of the oxygen-rich gas, each of the first and the second moisture filter having a multiplicity of pores.

16. The apparatus of claim 15, wherein the first and the second moisture filter are each formed by sintering polyethylene powder.

17. The apparatus of claim 15, wherein the pores of the first moisture filter have a sufficient size to allow condensates to pass therethrough into the first housing, and those of the second moisture filter have a sufficient size to prevent condensates from passing therethrough.

18. The apparatus of claim 15, wherein the second housing further contains an adsorbent for adsorbing moisture in the oxygen-rich gas in a flow path of the oxygen-rich gas.

19. The apparatus of claim 14, wherein the inlet of the second housing is located at a higher level than the outlet of the first housing so that condensates in the second housing gravitationally flow through the connection line into the first housing.

20. The apparatus of claim 8, wherein the first moisture filter is a hollow fiber membrane filter or a flat sheet membrane filter.

21. The apparatus of claim 9, wherein each of the first and the second moisture filter is a hollow fiber membrane filter or a flat sheet membrane filter.

22. The apparatus of claim 15, wherein each of the first and the second moisture filter is a hollow fiber membrane filter or a flat sheet membrane filter.
